(19) United States
(12) Patent Application Publication
(10) Pub. No.: US 2011/0030778 A1
(43) Pub. Date: Feb. 10, 2011

(54) Method of Passivating and Reducing Reflectance of a Photovoltaic Cell

(75) Inventors: Laszlo A. Takacs, Lakewood, OH (US); Roger F. Buelow, II, Gate Mills, OH (US)

Correspondence Address: BRUZGA & ASSOCIATES, 11 BROADWAY, SUITE 715, NEW YORK, NY, 10004, US

(73) Assignee: Energy Focus, Inc., Solon, OH (US)

(21) Appl. No.: 12/852,132

(22) Filed: Aug. 6, 2010

Related U.S. Application Data
(60) Provisional application No. 61/231,883, filed on Aug. 6, 2009.

(51) Int. Cl. H01L 31/04; H01L 31/18

(52) U.S. Cl. 136/256; 438/72; 257/E31.119

(57) ABSTRACT

Disclosed is a method of passivating and reducing reflectance of a silicon photovoltaic cell. The method includes the step of providing a silicon wafer of a solar cell having a major surface. A passivation layer of silicon nitride is applied on at least 98 percent of the major surface through a vacuum deposition process. An index-matching film structure, different from silicon nitride, is applied on top of the passivation layer. The index matching film structure provides the majority of the antireflective property of the combination of the passivation layer and the index matching film structure.

### FIELD OF THE INVENTION

The present invention relates to a method of applying various coatings or films on a silicon wafer in order to passivate the surface and reduce the reflectance of a photovoltaic cell.

### BACKGROUND OF THE INVENTION

Silicon semiconductor wafers, or substrates, are widely used in the fabrication of photovoltaic (PV) cells capable of converting solar light to electrical energy. To maintain high performance PV device, a layer of material, such as silicon nitride, is typically applied to the surface of the silicon wafer to reduce the surface recombination of electrons and holes, also known in the art as “surface passivation”. Silicon nitride is preferred due to its good passivation properties and reasonable optical properties.

In current silicon PV cell manufacturing, a widespread practice is to apply silicon nitride to a thickness of, typically, 1000 angstroms, which is more than the amount required to adequately passivate the silicon wafer. The relatively thick silicon nitride layer also reduces the reflectance of the PV cell, due to its relatively high index of refraction. Reducing reflectance results in a more efficient coupling of light and reduces the total amount of light reflected away from the PV cell. This allows a PV cell to more fully absorb and utilize photons from various directions during the transit angle of the sun. This can eliminate or reduce the need for special equipment to physically and continuously orient the PV cells to track the movement of the sun in the sky, and results in a greater amount of electricity gained from photovoltaic conversion.

One drawback of using silicon nitride for the dual purposes of passivating and reducing reflectance of a PV cell is that the silicon nitride layer is typically formed using a vacuum deposition process. Vacuum deposition techniques are costly to implement and require the largest and most expensive equipment used in PV cell fabrication. Not surprisingly, extensive use of vacuum deposition machines increases the total cost of manufacturing PV cells.

A further drawback of using silicon nitride for reducing reflectance of a PV cell is that its ability to reduce reflectance is limited in comparison to other materials. Various metal oxides possess significantly higher refractive indexes than silicon nitride and can function as considerably better anti-reflective coatings, though they lack passivation properties.

It would therefore be desirable to provide a method of passivating and reducing reflectance of a silicon PV cell that utilizes the excellent passivation properties of silicon nitride while reducing reflectance. Furthermore, it would also be desirable to limit reliance on costly vacuum deposition techniques in PV cell manufacture.

### BRIEF SUMMARY OF THE INVENTION

One form of the invention provides a method of passivating and reducing reflectance of a silicon photovoltaic cell. The method includes the step of providing a silicon wafer of a solar cell having a major surface. A thin passivation layer of silicon nitride is applied on at least 98 percent of said major surface through a vacuum deposition process. Afterwards, the inventive method calls for applying an index-matching film structure, different from silicon nitride, on top of the passivation layer. The index matching film structure provides the majority of the antireflective properties of the PV cell, while the silicon nitride functions primarily as a passivation layer.

The foregoing method utilizes the excellent passivation properties of silicon nitride while also reducing the reflectance of a silicon PV cell.

Preferred embodiments of the invention utilize a liquid phase deposition process using material produced through Sol-Gel chemical methods to provide an index-matching film structure atop the silicon nitride passivation layer. This results in a significantly lowered cost for manufacturing silicon PV cells because liquid phase deposition techniques are overall less expensive to implement and can be accomplished through a variety of means.

### BRIEF DESCRIPTION OF THE DRAWINGS

Further features and advantages of the invention will become apparent from reading the following detailed description of the invention in conjunction with the following drawings, in which like reference numbers refer to like parts:

FIG. 1 is a perspective view, in cross section, of a portion of a prior art photovoltaic cell.

FIG. 2 is flow chart that outlines manufacturing steps of the invention.

FIG. 3 is similar to FIG. 1, but shows modifications from the prior art in accordance with the invention.

FIG. 4 is similar to FIG. 3, but shows an alternative structure.

FIG. 5 is a graph comparing the reduction in reflectance of a prior art PV cell and an embodiment of the invention.

### DETAILED DESCRIPTION OF THE PREFERRED EMBODIMENT

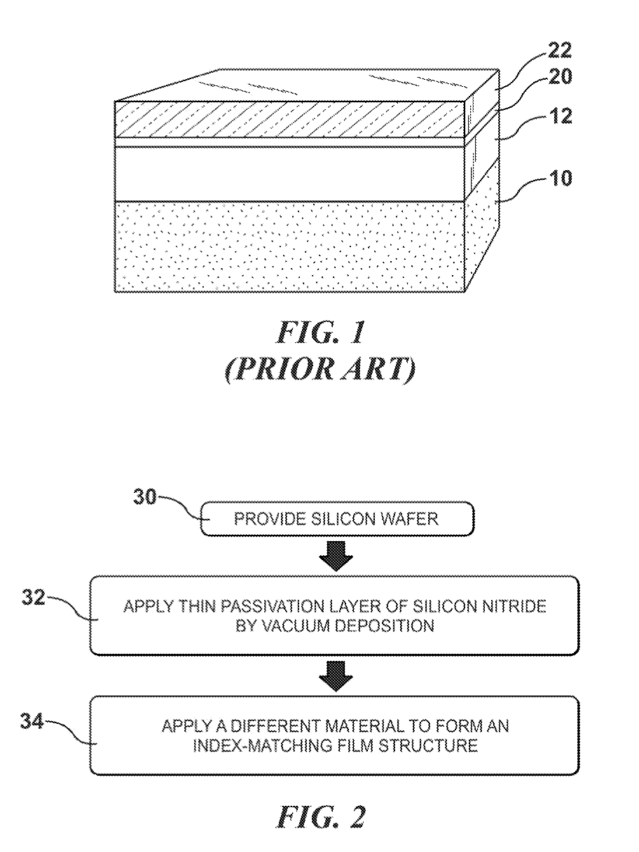

FIG. 1 shows a portion of a prior art silicon photovoltaic (“PV”) cell which is currently in widespread use. For clarity of explanation, the electrodes and p⁺or n⁻type doped regions are not shown. The PV cell includes a silicon semiconductor wafer 10, onto which various coatings or layers are applied. In a standard and widespread manufacturing technique, a single layer of silicon nitride 12 is applied onto a major (upper-shown) surface of wafer 10 for receiving photons. A standard technique for applying the silicon nitride layer 12 is by vacuum deposition, to a typical thickness of 1000 Angstrom. Thicknesses of layers as mentioned herein are average thicknesses, unless otherwise stated. Silicon nitride layer 12 functions to both passivate the surface of the silicon semiconductor wafer 10 that it overlies, as well as to reduce the reflectivity of the PV cell. Thus, in the prior art, the typically 1000-Angstrom thick silicon nitride layer 12 acts both as a passivation layer and as an anti-reflective (“AR”) coating.

Above the silicon nitride layer 12 in FIG. 1, a protective encapsulant such as glass is typically applied with an index-matching adhesive 20.

With reference to FIG. 2, step 30 of the inventive method provides a silicon semiconductor wafer, referred to in FIG. 2 (and sometimes hereinafter) by the shortened phrase “silicon wafer.” According to a subsequent step 32, a “thin” passivation layer of silicon nitride is applied to the silicon wafer of step 30 by vacuum deposition. At least about 98 percent of a photon-receiving surface of the wafer is covered by the silicon nitride layer to allow for manufacturing tolerance, and preferably all of such surface is covered. In comparison with the typically 1000-Angstrom thick silicon nitride layer 12 of prior art FIG. 1, the silicon nitride layer of step 32 is considerably thinner, as for instance less than 120 angstroms. As mentioned in step 32, the silicon nitride functions as a passivation layer, and by itself would only very poorly, if at all, reduce the reflectivity of the PV cell.

A subsequent step 34 in FIG. 2 provides a different film structure to complete what is known in the art as an index matching film structure or coating in a PV cell, where “index” refers to refractive index. A particularly preferred technique for applying the index-matching film structure is that of liquid phase deposition (“LPD”), for reasons that will be described below. The index matching film structure provides the majority of the anti-reflective property of the combination of the thin silicon nitride layer and the index matching film structure, and more preferably at least 90 percent of such property, and still more preferably at least 95 percent of such property.

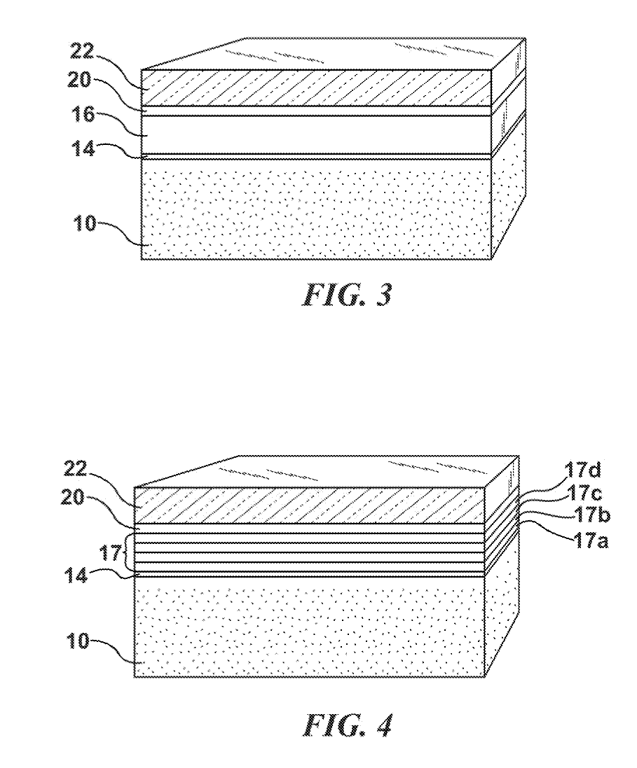

FIG. 3 shows a portion of a photovoltaic cell made through a preferred embodiment of the inventive method described above in connection with FIG. 2. The silicon semiconductor wafer 12 and silicon nitride layer 14 are applied as respectively described above in connection with steps 30 and 32 of FIG. 2. Above the thin silicon nitride layer, which is preferably below 120-angstroms thick, a single-layer index-matching film structure 16 is applied. The thickness of film structure 16 may typically be about 700 angstroms. Encapsulant 22, such as glass, may be applied with an index-matching adhesive 20, to protect the PV cell from the rain or dust, for instance. An AR coating (not shown) may be applied to the encapsulant, as is conventional.

The single-layer index-matching film structure 16 of FIG. 3 preferably comprises one of titanium (IV) oxide, tantalum (V) oxide, or niobium (V) oxide, by way of example.

Index-matching film structure 16 preferably is applied by a liquid phase deposition (“LPD”) process, especially one that utilizes material produced using a Sol-Gel process. A typical and preferred Sol-Gel process used involves the reaction of one or more metal alkoxides corresponding to a desired deposition material in a suitable solution under acidic conditions to form extended metal oxide chains capable of condensing to form three-dimensional networks. The foregoing formulation is a general Sol-Gel formulation description. Specific formulae encompassed within such general formulation will be routine to those of ordinary skill in the art.

Beneficially, the LPD can be accomplished using any of a variety of approaches, including:

Liquid Dip;

Spin Coating;

Spraying; or

Meniscus-Controlled Deposition.

All of the foregoing LPD of material produced using Sol-Gel processes use far less costly equipment than vacuum deposition techniques used for applying the preceding silicon nitride layer 14. Not only is there is flexibility in choosing which equipment to use for applying index-matching film structure 16 of FIG. 3 with the foregoing LPD of material produced using Sol-Gel process, but such process allows for reduced manufacturing cost. Liquid Phase Deposition of material produced using a Sol-Gel process allows a greater production throughput on much-less expensive equipment than the sole reliance on vacuum deposition techniques used to produce the relatively thick silicon nitride layer 12 of prior art FIG. 1. By using vacuum deposition techniques to apply a minimal “thin” passivation layer, while applying an anti-reflective coating through a liquid phase deposition, manufacturing costs are significantly reduced.

FIG. 4 shows a PV cell that differs from the PV cell of FIG. 3 by replacing single-layer index matching film structure 16 with a multi-layer index matching film structure 17. In particular, multi-layer film structure 17 preferably comprises a multi-layer optical interference coating having alternating layers with different indices of refraction. Such alternating layers are schematically illustrated by layers 17a, 17b, 17c and 17d; however, the number of such layers is typically much higher than four and the layers are thinner than as shown. Such an optical interference coating may be applied with vacuum deposition techniques. Or, such an optical interference coating may be applied with the LPD of material produced using various Sol-Gel processes mentioned above. Preferred materials for a multi-layer optical interference coating are a layer of silicon dioxide alternating with a layer of any of one of titanium (IV) oxide, tantalum (V) oxide, or niobium (V) oxide.

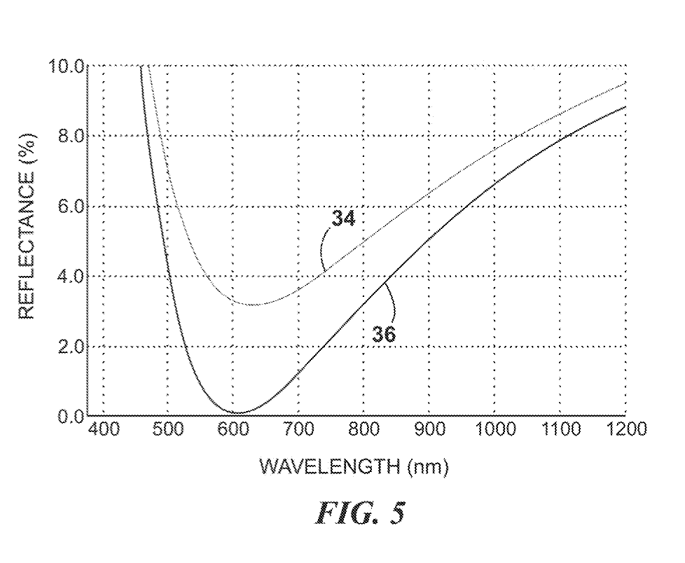

FIG. 5 shows a reduction in reflectance of a PV cell for an embodiment of the present invention compared with the prior art PV cell of present FIG. 1. For both the inventive PV cell and the prior art PV cell, it is assumed that the encapsulant 22 (FIGS. 1 and 3) is not provided with an anti-reflective layer. Curve 34 shows reflectance for the prior art PV cell of FIG. 1, and exhibits about 3.5 percent reflectance at 600 nm wavelength of light. Curve 36 shows a considerably reduced reflectance of about 0.2 percent reflectance for the PV cell of FIG. 3, wherein the single-layer index matching, film structure 16 is titanium oxide with a thickness of 700 angstroms. The reduction in reflectance translates to an increased receptivity of light, such as, for instance, light at high angles relative to orthogonal to the main surface of the silicon wafer 10 that would otherwise reflect off the PV cell. This allows a PV cell that is permanently or temporarily stationary to more fully absorb and utilize photons from the sun during a greater transit angle of the sun. This can eliminate or reduce the need for special equipment to cause the PV cells to track the moving the sun in the sky, and results in a greater amount of electricity from photovoltaic conversion.

In addition to exhibiting reduced reflectance, the use of the LPD techniques using material produced through Sol-Gel processes as described above significantly reduces manufacturing cost. For instance, silicon nitride layer 14 of FIGS. 3 and 4, when applied to a thickness of 90 angstroms in the present invention, requires only about one-tenth the time of the expensive vacuum deposition process contemplated by the prior art silicon nitride layer 12 of FIG. 1, which typically has a 1000 Angstrom thickness. The single-layer film structure 16 of FIG. 3 and the multi-layer film structure 17 of FIG. 4 can be made by the far-less costly LPD using material produced through Sol-Gel process described above. Moreover, as discussed previously, the LPD of material produced using Sol-Gel process can be accomplished in a variety of ways including but not limited to liquid dipping, spin coating, spraying of meniscus-controlled deposition. Additionally, the multi-layer film structure 17 of FIG. 4 can still be formed through vacuum deposition techniques. This makes manufacturing of the film structures 16 and 17 of FIGS. 3 and 4, respectively, more versatile.

While the invention has been described with respect to specific embodiments by way of illustration, many modifications and changes will occur to those skilled in the art. For instance, an intermediate step or steps may occur between the various steps of the inventive method. Thus, between the application of the silicon nitride layer and the application of the subsequent film structure a step or steps for applying to the PV cell metallization for electrodes may occur. Further, although the surface of the silicon wafers may be flat, such surfaces may also be textured as will be routine to those of ordinary skill for increasing surface area of the wafer receptive to absorbing photons used for photovoltaic conversion. It is, therefore, to be understood that the appended claims are intended to cover all such modifications and changes as fall within the true scope and spirit of the invention.

What is claimed is:

1. A method of passivating and reducing reflectance of a silicon photovoltaic cell, comprising the steps of:
a) providing a silicon wafer of a solar cell having a major surface;
b) applying a passivation layer of silicon nitride on at least 98 percent of said major surface through a vacuum deposition process; and
c) applying an index-matching film structure, different from silicon nitride, on top of the passivation layer;
d) the index matching film structure providing the majority, of the antireflective property of the combination of the passivation layer and the index matching film structure.

2. The method of claim 1, further comprising the step of applying an adhesive layer on top of the index-matching film structure for receiving an encapsulant.

3. The method of claim 1, wherein the index-matching film structure provides at least 90 percent of the antireflective property of the combination of the passivation layer and the index-matching film structure.

4. The method of claim 1, wherein the silicon nitride passivation layer has an average thickness of less than about 120 angstroms.

5. The method of claim 1, wherein the index-matching film structure comprises a single layer of titanium dioxide.

6. The method of claim 1, wherein the index-matching film structure is a single layer of titanium dioxide applied by liquid phase deposition.

7. The method of claim 6, wherein material to be deposited in the liquid phase deposition is produced through a Sol-Gel process.

8. The method of claim 1, wherein the index-matching film structure is a single layer of tantalum (v) oxide applied by liquid phase deposition.

9. The method of claim 8, wherein material to be deposited in the liquid phase deposition is produced through a Sol-Gel process.

10. The method of claim 1, wherein the index-matching film structure is a single layer of niobium (v) oxide applied by liquid phase deposition.

11. The method of claim 10, wherein material to be deposited in the liquid phase deposition is produced through a Sol-Gel process.

12. The method of claim 1, wherein the index-matching film structure comprises a multi-layer optical interference coating having alternating layers of material with different indices of refraction.

13. The method of claim 12, wherein the optical interference coating comprises silica and one of titanium (IV) dioxide, niobium (V) oxide, and niobium (V) oxide.

14. The method of claim 12, wherein the optical interference coating is applied by a liquid phase deposition Sol-Gel process.

15. A photovoltaic cell made according to the process recited in claim 1.

16. A photovoltaic cell made according to the process recited in claim 6.
